(19) United States
(12) Patent Application Publication
(10) Pub. No.: US 2024/0195397 A1
(43) Pub. Date: Jun. 13, 2024

(54) USB-C and Other Cable Accessories

(71) Applicant: Xiaozheng Lu, Dallas, TX (US)

(72) Inventor: Xiaozheng Lu, Dallas, TX (US)

(21) Appl. No.: 18/531,623

(22) Filed: Dec. 6, 2023

Related U.S. Application Data
(60) Provisional application No. 63/430,803, filed on Dec. 7, 2022.
(60) Provisional application No. 63/541,792, filed on Sep. 30, 2023.

(51) Int. Cl. H03K 5/1252; H01B 11/00; H01R 31/06; H02M 3/00

(52) U.S. Cl. CPC H03K 5/1252; H01B 11/00; H01R 31/065; H02M 3/003

(57) ABSTRACT

This patent application is represented by embodiments a variety of cables, Dongles, Locking Sleeves, bulk wire, Long-Distance DC-DC Converter Circuitry and PD Adapter for transmission of digital signals over long cables that may be combined in multiple embodiments.

### CLAIM OF PRIORITY

This application claims priority to U.S. Provisional Application No. 63/430,802 filed Dec. 7, 2022, and U.S. Provisional Application No. 63/541,792 filed Sep. 30, 2023.

### FIELD OF THE INVENTION

The invention relates to new technologies and designs in communication cables that solve the problems of sending large power (in Watts or W) through very long and relatively thin copper conductors; sending legacy two-way communication signals that requires bi-directional devices sensing through very long cables; converting existing long cables that were not designed to carry the above power tasks. Embodiments do so by adding short Dongles with circuitry at each end of the cable; inner DC-DC converter circuits to power the internal circuits and external source device inside the long cable; inner Vbus line switch to allow two sides of the long cable to have different PD voltages; Locking sleeve that secure the Dongle to the end of the long cable are provided; plus, a new way of dividing the shieling areas to achieve complete electromagnetic interface (EMI) shieling on one section of the PCB, while allowing other sections to have open windows for status indicators visible to the user. Embodiments include some or all of these inventions to form a whole set of solutions for sending large power (in Watts or W) and special signals through very long cables. Other embodiments include adding a PD Adapter in between the long cable and devices that maneuver the CC line communications for recognition or handshaking between devices and PD management. Such embodiments solve the incompatibility issues between devices and long cables. The embodiments of the present invention have many useful applications in long USB or HDMI, fiber or active cables among other commercial cable formats and even applications to proprietary and newly developed formats.

### BRIEF DESCRIPTION OF THE DRAWINGS

FIG. 1 schematically shows a prior art long cable with male connector at each end.

FIG. 2 schematically shows one embodiment of the current invention comprising long USB-C fiber AOC cable's internal circuit block diagram with the USB 2.0 Tx/Rx circuit for long distance transmission and the DC-DC converter circuit for large power long distance transmission.

FIG. 3 schematically shows one embodiment of the current invention comprising long USB-C fiber Active Optical Cables (AOC) cable's internal circuit block diagram with the USB 2.0 Tx/Rx and DC-DC converter circuits moved out to a pair of external dongles shown in FIG. 4.

FIG. 4 schematically shows one embodiment of the current invention comprising a Dongle's external body and features that has the USB 2.0 Tx/Rx and/or DC-DC converter circuits from FIG. 2 to be used for adding these 2 features for the long cables in FIG. 3 that currently do not have these 2 circuitries.

FIG. 5 schematically shows one embodiment of the current invention comprising a Dongle's internal circuit block diagram with the USB 2.0 Tx/Rx circuit for long distance transmission and the DC-DC converter circuit for large power long distance transmission.

FIG. 6 schematically shows one embodiment of the current invention comprising a Locking Sleeve's external body and features with views from 5 different angles.

FIG. 7 schematically shows a prior art internal PCB (Printed Circuit Board) with the overall metal shielding shell that has openings for the LED (Light Emission Diode)'s lights to be visible from outside and thus also allows the EMI (Electro Magnetic Interference) to come in and out from the openings.

FIG. 8 schematically shows one embodiment of the current invention comprising an internal PCB similar to the embodiment in FIG. 7, but where the PCB is divided into 2 or more sections by EMI shielding metal walls, which maintain the complete airtight EMI shielding for the section with high frequency signals while still allowing the LEDs to be visible from the section without high frequency signals.

FIG. 9 schematically shows a prior art bulk wire cross section view with internal conductors and shielding layers shown.

FIG. 10 schematically shows one embodiment of the current invention fiber bulk wire's cross section with the shielding layer removed to reduce capacitance.

FIG. 11 schematically shows one embodiment of the current invention comprising inner power circuits inside a long cable that raises low PD voltage on one end of the long USB-C cable to an internal higher voltage, sends it to the other end of the cable, then converts down to the low voltage to power the inner circuits and the external device without the voltage drop thru the long cable.

FIG. 12 schematically shows one embodiment of the current invention comprising an inner Vbus line switch circuit inside a long cable that cut off the connections between the Vbus pins between the two ends of the long cable when the Vbus voltage on one end falls to certain range to allow more complex PD voltage arrangements while keep the connections between the Vbus pins between the two ends of the long cable when the Vbus voltage on end is not in that certain range.

FIG. 13 schematically shows one embodiment of the current invention comprising a PD Adapter device's internal circuit block diagram with PD Controller microchip in between the CC line of the two ends of the PD Adapter and maneuvers the CC line communication data to solve PD power and other compatibility issues like DP video configurations between devices and long cable. Also shown is an optional DP controller in between the input and output of this adapter to manage the number of USB-C signal lanes to be used for DP video.

### BACKGROUND

There is a large demand for long communication cables in the real world, especially in the field of consumer electronics, corporate media, and various industrial applications. The cables linking a computer below the desk to a monitor on the desktop typically only need to be 1 to 2 m (meter; or 3 to 6 feet) long. The cables linking a media player in an equipment rack at the corner of a conference room to a large flat screen TV in the front of the conference room typically need to be 5 to 10 m (or 15 to 30 feet) long. The cables linking a main computer in the adjacent equipment room to an overhead projector in a conference room typically need to be 30 to 100 m (or 100 to 300 feet) long. The cables linking between devices between buildings often need to be few km (kilometer, or few miles) long. Undersea cables linking continents are generally in the hundreds to thousands of km (or miles) long.

Currently long USB-C 3.2 cables are made of Active Optical Cable (AOC) that use several fiber strands to send very high-speed USB and DP data with relative ease. However, these USB-C AOC cables often need to be backwards compatible with the legacy USB 2.0 signals. There are two ways to send the USB 2.0 signals through the long cable: one is to use fiber strands just like the USB 3.2 signals; however, this is an expensive solution, because two new fiber transmitters (Tx), receivers (Rx), fiber strands, and electrical to optics converting circuits need to be added to the cable and connector. Further, this fiber strand solution is often not reliable because the USB 2.0 signal was designed for copper cables which is able to facilitate bi-directional transmission to detect multiple devices or ICs on the same line. In contrast, fiber is a one-way transmission method and won't detect devices on the same line as is possible with copper cables. The other way to send USB 2.0 signals is to just use the passive conductors for long distances; however, this often stops working for the cables longer than 5 m (17 feet) due to excessive capacitance between the conductors that limits the signal voltage's transitions between 0s and 1s. Also, when a system uses a very long cable in the range of 50 m (164 feet), the devices connected to the two ends of the long cable most likely are in two different locations or rooms, and may not be in the same AC power ground or even phase; this means that there could be potentially large voltage differences between the two group of devices, that can introduce large interference to the USB 2.0 signals or even large voltage surges that can damaged the connected devices by such long cables, because the standard USB 2.0 circuit is DC coupled.

For the convenience of the consumer or industrial users, modern products like long (50 m or 164 ft) USB-C cables have a feature to send up to 100 W (Watts) power from one end to the other to power a device at the far end. For example, a 50 m (164 feet) long USB-C cable connected to a big projector on the ceiling where the projector can send 60 W power through the long USB-C cable to the conference tabletop. In such scenarios the long USB-C cable can get the video signals from the meeting presenter's laptop, and at the same time receive power over the cable to charge the laptop, so the presenter does not have to bring in his charger and look for a power outlet at the conference table.

The 60 W carrying through this 50 m (164 feet) long USB-C cable (most likely a fiber AOC cable) is required for a large current to be sent through the Vbus and ground conductors. These conductors often need to be as big as 10 AWG in size or even larger depending on the cable length and power delivery (PD). A single 10 AWG conductor alone has a diameter of 2.6 mm not counting the insulation layer wrapping it; just the raw copper material needed to make a pair of this conductor for 60 W to 100 W power transfer at 50 m (164 feet) long is already approaching USD $100. These 10 AWG conductors made cables become very stiff due to the thickness from large conductors, and are not at all user friendly; also, they are quite expensive to make, giving the current high prices quantities of the copper material required for the conductors. Thus, embodiments also significantly reduced costs with improved fully functional signal transmission with long cables.

Many attempts by multiple inventors in the past 16 years have sought to solve these problems recited above and have not been successful. The prior art has been focusing on using very thick conductors in the long cables to send a large amount of power. This results in the thick and rigid cables that are undesirable and often unusable. The prior art has also been trying to send the USB 2.0 signals through long cables assuming the cable's capacitance can't be reduced thus focusing on reshaping the round-corner signals received at the far end. However, this approach will not solve the timing delays caused by large capacitance of such long cables.

There are many other incompatibility issues caused by the USB-C specifications not being designed for long cables; for example if the Display device sends 20 V through a long cable, and in such cases the Source device only receives 18 V due to the voltage drop over the long cable, the Source device may sends a low voltage warning via the CC communication line to the Display device; and then the Display device would shut down the 20 V and try to resend it again. This sending and shut down due to insufficient voltage will repeat again and again in cycles causing inoperability for the cable and the connected devices.

### SUMMARY

One group of embodiments of this invention deals with the challenge of sending USB 2.0 signals through long cables by adding the transmission (Tx) circuit at one end of the cable to use alternating current (AC) coupling to cut off any potential ground voltage difference caused by connecting two groups of devices in different rooms, and also to change the signal to balanced signal format and circuitry that does not need a ground, to send through long cable, then uses receiving (Rx) circuits at the other end of the cable to convert the signal back to the original form defined by the USB 2.0 specifications (specifications or specs). The balanced signal long distance transmission circuitry embodiments also canceled out, at the receiving end, any interference signals injected into the long wires during transmission by subtracting the two signals in the + and − wires of the balanced pair.

The other group of embodiments of this invention is to deal with the challenge of sending large amounts of power through long cables from a completely different approach: by using a DC-DC converter at one end to raise the power voltage to many times higher from USB specs, and at the far end to use another DC-DC converter to lower the power voltage to the lower voltage defined by the USB specs. This way the current flowing long cable's conductors are dramatically reduced by many times, which allows use of conductors of much smaller size (AWG) to be used for the same power transmission, thus these embodiments reduce the amount of copper used and the final cable costs, and also allows the cable to be much thinner and more flexible. These embodiments of the current invention comprising DC-DC converter circuits can be configured in the long cable's plugs; or can be configured in a circuit board somewhere in the middle of the long cable. Another embodiment of the current invention incorporates the Long-Distance DC-DC Converter Circuitry into a pair of Dongles for use with one at each end of the long cable, each Dongles configured with a female connector for the long cable male connector to plug in; and with a male connector to plug in to the device; and with a short bulk wire in between the Dongle body and the male connector.

Not all applications require the USB 2.0 backwards compatibility or the remote power delivery (PD). In such scenarios, it makes sense to have embodiments that remove these two circuitries from every long USB-C cable and move them into a pair of short dongles that can be plugged into each end of the long USB-C cable only when one or both of these two circuits are needed. In commercial settings the manufacturers can make different embodiments where some Dongles have both circuitries; and some Dongles have only one of these two circuitries. This gives the users the choice to only pay for the Dongles with the feature(s) they actually need. Embodiments of these Dongles are also very useful products to be added to legacy USB AOC cables already installed inside the office building walls that were not designed for any remote power delivery and/or USB 2.0 backwards compatibility in mind and now can be converted to have these features.

Embodiments of the Dongles have a female USB-C connector for the long USB-C cable's male connector to plug in. To prevent the Dongles from becoming loose from the long USB-C cable or stolen from the conference rooms, classrooms, or other location embodiments may also include a Locking Sleeve that can be easily slide over the long USB-C cable and then slip over the its male connector, and reaching out to the Dongle body and then be permanently locked by a security screw to the Dongle's body.

Modern electronics devices and cables including the USB-C cable plug body and the Dongle body often contain LEDs to indicate the signal and power types and status. The small opening holes for the LED light to come out and be visible also allows the EMI leaking signals to come out or to go in, and potentially cause interference to these connected devices or other nearby devices. Embodiments for the current invention also include a compartmentation configuration placing the high frequency EMI sensitive signal components and traces on one portion of the PCB while placing the DC signal components including the LEDs and traces on the other portion of the PCB, and adding the thin metal (e.g., copper) walls to isolate these two portions thus maintaining the air tight and also EMI tight shielding on the portion of the PCB with the high frequency EMI sensitive components while still providing the LED indications needed for monitoring signals.

The communication lines in the video and data cables all have the maximum allowed capacitance to ensure the maximum time delay on the data; for example, the maximum allowed capacitance on the HDMI DDC line is 700 pF; the maximum allowed capacitance on the USB CC line is 600 pF. This is not a problem for the short cables like the 2 m cable. However, this allowed capacitance issue becomes a huge problem for the long cables like the 50 m cable, whose line capacitance is 25 times of a 2 m cable if the bulk wire is the same. Embodiments of the current invention changes the transmission media of the high-speed video data lines like the TMDS lines or FRL lines in HDMI, or the SBU lines (DP) in USB, and the high-speed data line like the Tx and Rx lines in USB from copper wires to fiber optics, completely eliminates the EMI emissions.

Other embodiments of the current invention described in paragraph change the transmission method of the low-speed data lines line the DDC lines in HDMI and the CC line and D line (USB2) from single ended transmission to balanced transmission. Embodiments of the current inventions dramatically reduced the EMI emissions from the bulk wires, which allows other embodiments of the current invention to remove the overall shield layer of metal in the HDMI or USB bulk wires to further reduce the low-speed line to ground capacitance, to allow them to meet both the small data line capacitance and the small EMI emission requirements. These also lead to overall cheaper, thinner and softer bulk wires that can be used commercially in a variety of applications.

The embodiment of the current invention comprises Dongles described in paragraph and can help to send 60 or 100 W PD power across long cable in between. When the 60 or 100 W power is not needed thus the Dongles are therefore not needed, however there is still a need for smaller power in certain situations like for example for 5 V 1 to 3 A (5 to 15 W) power to be sent to the far end of the long cable to power the internal circuit of the cable and/or the external device connected to the cable for a security camera or like device. Embodiments of the current invention also have an internal circuit in the long cable, with a small DC-DC converter at one end to raise the low voltage like 5 V to a higher voltage like 20 V, to send it through a dedicated bulk wire conductor (for example we call it Vint line) to the far end of the cable, then it comprises another small DC-DC converter to lower the voltage to voltage needed there like 5 V. These embodiment cables comprise small DC-DC converters that are small enough to fit in the long cable's plug bodies, and cheap enough for the long cables to still be economical.

The 5 V power in the USB specs is an old spec, and often with very limited current like 0.9 A or 1.2 A, and the like. Even with embodiments of the current invention comprising internal DC-DC converter circuits described in paragraph that can maintain the 5 V voltage at the far end of the cable, the cable would draw more current than the far end device due to the energy loss in the long cable. For example, if the far end camera draws 0.9 A in 5 V; then the long cable's near end would draw like 1.3 A in 5 V. This situation could trigger over current protection by the device connected to the near end which is undesirable and would result in the connected devices to shut down the USB connection and report error. Embodiments of the current invention solve this kind of problem by requesting higher voltage for example 20 V from the near end device while still sending the low voltage of for example 5 V to the device connected at the far end of the long cable. This way because the voltage requested at the near end of the cable like 20 V is 4 times higher than the voltage supplied at the far end of the cable like 5 V, the current draws from the near end device is only ¼ of the supplied current to the far end, and thus would never trigger an over current protection problem. However, both power pins at the near end and far end of the long cable are connected by the same Vbus line conductor. Embodiments of the current invention further solves this issue by adding circuits inside the long cable in the near end to detect the Vbus line voltage, and would only cut off (open) the Vbus connection between the near end and far end in a narrow range of voltage like around 20 V to allow the different voltage described above to exist, while still keeping the Vbus line connection between the near and far end when the Vbus line voltage is outside this narrow range. This ensures the Vbus line would function during the USB's handshaking process in which the voltage is 5 V or 0 V.

Since the USB specifications were not written with the long cables in mind, even embodiments of the well designed and well-made current invention long cables and source and display devices can still run into compatibility issues. For example, a 10 m fiber AOC USB-C cable connected to a laptop and a docking station together presents compatibility issues. For example, the docking station can send 20 V 3 A (60 W) PD power over this long cable; the laptop only receives 18.5 V 3 A power, and could report to the docking station via the CC line as low voltage warning; then the docking station could shut down the PD power and restart and repeat this cycle forever resulting in cable inoperability. In another such example, at the very first moment when the long cable is connected, the 5 V voltage could momentarily fall to very low like the 1.5 V due to the capacitance charging but quickly back up to 5 V. Laptops would monitor the Vbus line voltage right at the moment the cable is plugged in, and detect this very brief low voltage and report this as a low voltage warning to the docking station via the CC line. Then the docking station would shut down, re-start and repeat again and again resulting in cable inoperability. There could be many other such examples for compatibility resulting in cable interoperability like the number of lanes used for the DP video in the USB-C signaling. Embodiments of the current invention including a small device called a PD Adapter, which has a female USB-C connector for the long cable's male connector to plug in, and a male USB-C connector at the other end of a short bulk wires in between to allow it to plug into the external device. Embodiments of this PD Adapter comprise a micro controller in between the CC line from the near and far end of the long cable that breaks down the direct communication between the near and far end external devices, and communicates with each one separately. This allows the micro controller in embodiments of the current invention PD Adapter to act as a 3^{rd} device in between and can talk with the two connected devices in different communication data based on the long cable and connected devices, charging power needs and supplies, to allow the system to work without shutting down and restarting over and over again, solving the new issues from the very long cables in between devices in a different way to make them work with the current USB specs not written for long cables.

Embodiments include firmware for the PD Adapter that can be updated regularly to allow it to fix new compatibility issues learned over time by the manufacturers. Other embodiments include a DP Controller micro controller IC in between the input and output of this adapter to manage the number of USB-C signal lanes to be used for DP video.

Although the Figures and specifications of cables for embodiments in the patent application only use USB-C AOC cables as the examples, these embodiments of the present inventions can be used in USB, HDMI, DP, SDI, IEEE 1394, Thunderbolt, Lighting cables, or other formats, or mixtures thereof and many other types of cables to solve the similar problems, and should be all considered as additional embodiments of this invention.

Although the Figures and specifications of embodiment Dongles in the patent application only use USB-C Dongles as the examples, these inventions can be used in USB A Dongles, USB B Dongles, the Dongles with mixed USB connector types and genders, HDMI Dongles, DP Dongles, and many other types of connector families to solve the similar problems, and should be all considered additional embodiments.

Although the Figures and Specifications of Locking Sleeve in embodiments of the patent application only use USB-C Locking Sleeve as the examples, these embodiments can be used in USB A Locking Sleeve, USB B Locking Sleeve, the Locking Sleeve with mixed USB connector types and genders, HDMI Locking Sleeve, DP Locking Sleeve, and many other types of connector families to solve the similar problems, and should be all considered additional embodiments of this invention.

Although the Figures and Specifications of Bulk Wires in embodiments the patent application only use USB-C Bulk wire as the examples, these embodiments can be used in bulk wires of USB, HDMI, DP, SDI, IEEE 1394, Thunderbolt, Lighting cables, or other formats, or mixtures thereof, and many other types of wire families to solve the similar problems, and should be all considered additional embodiments of this invention.

Embodiments include a communication cable comprising a cable having at least a first end and second end and at least one jacket; a plurality of conductors placed within the cable; at least two connectors, where a connector is attached at first end and a second end of the cable; at least one printed circuit board configured within or near the end of each of the at least two connectors, or where the printed circuit board is disposed in or near the middle of the cable, where each of the printed circuit boards further comprises the first set of circuits, or the second set of circuits or both sets of circuits or subset of circuits of each of a first set of circuits and/or second set of circuits, the first set of circuits further comprising, at least one balanced signal driver circuit, to reduce the emissions from at least one signal conductor pair to the outside environment and also to reduce outside EMI interferences with the signal in the at least one signal conductor pair; at least one AC (Alternating Current) coupling capacitor to cut off the large ground potential differences between devices connected to the at least one connector of the cable; a signal transmitter (Tx) circuit in one of the printed circuit boards that converts the data signal into a balanced signal for long distance transmission, a signal receiver (Rx) circuit in one of the printed circuit boards of the cable that converts the balanced signal back to the original signal format; the second set of circuits comprising, a first DC (Direct Current) to DC converter configured in at least one of the printed circuit boards that changes the DC power voltage to up to multiple times higher, to send through the conductors inside the cable from one end to the other end; a second DC-DC converter in at least one of the printed circuit boards that converts the power voltage either to the same voltage that is disposed into the near end of the cable or to a voltage set by the user for the devices connected an end of the cable. Added embodiments may further comprise one or more fiber channels, where the cable is a USB-C 3.2 AOC (Active Optical Cable), and/or the USB 3.2 signals and/or DP (DisplayPort) signals are sent through the fiber optics channels, and/or the legacy USB 2.0 signals is sent through the balanced signal driver circuit with optional AC coupling; and/or the DC-DC converter converts the incoming about 5 V, about 9 V, about 15 V or about 20 V to up to about 48 V, and sends the voltage through the long cable; then converts the voltage back to the same voltage as the incoming power, or to a voltage set by the user. Other embodiments include a pair of communication cable Dongles system comprising a first and second Dongle each comprising a cable with a first end and second end for transmission of digital signals; each Dongle further comprising a Dongle body; a first and second connector; where the first or second Dongle or both Dongles have the first connector configured for the cable to plug into the first connector; a second or a third short cable configured on one end of the first or second or each Dongle body or both Dongle bodies; a second connector at the end of each of the second or third short cable from the first or second or both Dongle bodies is configured to plug into a device outside this Dongles system; where each Dongle has at least one printed circuit board, each Dongle's printed circuit board further comprises at least one of the following sets of circuits, a first DC-DC converter circuit at the first or second end of the first cable, where the DC-to-DC converter circuit increases the DC power voltage to up to multiple times higher than the incoming DC power voltage, and where the voltage changed DC power is sent through the power conductors inside the cable to the other end; a second DC-DC converter circuit, where the second DC-DC converter circuit is configured inside the first or second Dongle, where the first or second Dongle is connected to the other end of the first cable, and where the second DC-DC converter circuit converts the power voltage either to the same voltage that comes in into the first end of the first cable or to a voltage set by the user for devices connected to this second Dongle; and an optional PD Controller that connects in between the external device and the long cable via the communication line, to allow the long cable to have different power voltage inside the long cable from the inner power voltage from the connected device; and also allow the PD Controller to fix different incompatibility issues via the communication line; an optional signal driver circuit comprising a coupling capacitor where the single driver circuit converts the data signal into a balanced signal for long distance transmission, and the coupling capacitor uses AC current to cut off the large ground potential differences between devices connected to the first and second ends of the first cable; an optional signal receiver circuit inside the first or second Dongle connected to the first or second end of the cable, where the single receiver circuit converts the balanced signal back to the original signal format. Other communication Dongles include where the connector configured at the Dongle body is a female USB-C connector; and the connector configured at the other end of the short second or the third cable that connected to the first or second Dongle body is a male USB-C connector; and where the first cable is a USB-C 3.2 AOC cable further comprises; one or more fiber channels, the USB 3.2 data signals and/or DP (DisplayPort) video signals are sent through the fiber optical channels, and/or one or more copper conductors, the legacy USB 2.0 signals is sent through the balanced signal driver circuit with AC coupling converted inside the Dongles via the copper conductors of the first cable; and/or the DC-DC converter converts the incoming about 5 V, about 9 V, about 15 V or about 20 V to up to about 48 V inside one Dongle, and converts to the same voltage as the incoming voltage or a voltage set by the user inside the other Dongle. Still other communicate cable embodiments include features described prior plus formats of the cable consisting of USB, HDMI, DP, SDI, IEEE 1394, Thunderbolt, Lighting cables, or other formats, or mixtures thereof. Related embodiments include a Locking Sleeve comprising a chamber with a first opening in the front that can allow a connector body of a male connector of a cable to slide in; an open slot on the bottom of the chamber configured to allow a bulk wire of a cable to side up into the chamber; a flap connected to the top of the chamber and extended forward to the front of the chamber of the sleeve; the flap further comprising a hole on the front portion of the flap configured to allow a security screw to go over from the top down; when the cable's connector is plugged into the connector on a Cable Accessory's main body, the Locking Sleeve can be slide down onto the cable's bulk wire portion away from the male connector body, then slide forward until it wraps around the male connector body, and its Flap goes over to the top portion of the Cable Accessory's main body, then a security screw can be screwed down through the Flap into the female screw hole in the Cable Accessory's main body, to form a permanent lock between the cable's male plug and the Cable Accessory. Other related embodiments include bulk wires in cables describes previously, where the conductors for communication are laid inside the jacket of the bulk wires; and where there is no overall shielding metal foil or braiding around the bundle of the conductors. Embodiments also include the Long-Distance DC-DC Converter Circuitry system comprising a long cable comprising conductors a wrapping and jacket surrounding the conductors forming a bulk wire; a male or female connector on each end of the long cable; a first and second device, where each device can connect to circuitry configured in the long cable; the circuitry further comprising a first DC-DC converter to convert an external power from the near end connector of the long cable connected to an external device into an Inner Power with a different voltage; where the first DC-DC converter sends the Inner Power to the far end of the long cable via the conductors in the bulk wire; a second DC-DC converter where the Inner Power received at the far end of the long cable is sent from the first DC-DC converter to convert to another voltage needed from a first or second device and that feeds to the other circuits in the far end of the long cable; where the converted voltage is also fed to the second device connected to the far end of the cable; the circuitry in the cable further comprising an “OR” circuit formed by a diode or other components that only allows the power with higher voltage to go through to the connected external first or second device between the converted power via the Inner Power conductor and the not converted power via the standard conductor of the bulk wires. Other related Long-Distance DC-DC Converter Circuitry embodiments to those just described further comprise Legacy Upgrading Circuitry, the Legacy Upgrading Circuitry further comprising an electronic switch component connecting in between the near end and far end of the standard power conductor, a Control circuit that acts based on the voltage of the standard power conductor of the long cable's near end; a Switch; where the voltage of the standard power conductor's near end is in some ranges, the Control circuit will turn on the Switch and connect the near end and far end of the standard power conductors together as one wire; while when the voltage of the standard power conductor's near end is in another range, the Control circuit will turn off the Switch and disconnect the near end and far end of the standard power conductors thus allow the near end and far end of these standard power conductors to have different voltages. Other related embodiments include a PD Adapter accessory comprising a first and second connector body; a short bulk wire comprising conductors comprising a first end and a second end where the first end is connected to the first connector body and the second end is connected to the second connector body; a communications conductor disposed inside the short bulk wire, a female connector disposed on the first or second connector body; a male connector disposed on the first or second connector body; a printed circuit board (PCB) configured inside the first end of the connector body further comprises a PD Controller micro controller IC, where the PD Controller communicates with a device connected to the female end of the PD Adapter and with a device connected to the male end of the PD Adapter separately with different parameters via the communication conductor; optionally a DP Controller micro controller IC in between the input and output of this adapter to manage the number of USB-C signal lanes to be used for DP video; and firmware embedded in or loadable into the PD Adapter where the firmware can be updated by user to expand the incompatibility fixes or adding features. Still further embodiments include a long communication cable comprising a cable comprising conductors; where at least one of the conductors is an Inner Power (Vint) conductor; at least two connectors for connecting to a display and a source device; at least two active optical cable circuits; a plurality of circuitry further comprising; at least one Long-Distance DC-DC Converter Circuitry; and optionally a Legacy Upgrading Circuitry optionally a balanced long-distance driver and transmission circuitry. Related embodiments to the cable just described include Long-Distance DC-DC Converter Circuitry that further comprises at least one of the DC-DC converters; where the first DC-DC converter increases a voltage from a connected display to a set voltage; the second DC-DC converter decreases the voltage to a lower standard set voltage for use by a connected first active optical cable circuit; and the third DC-DC converter decreases the voltage for use by a second connected active optical cable circuit and a connected source device. Still further embodiments include the long communication cables described previously, where the Vint conductor is configured to carry about 5 V to about 48 V. Related embodiments to the cable just described include cables where the balanced long-distance transmission circuitry further comprises balanced conductors (3 conductors: + and − and ground) chosen from the group consisting of a CC conductor, a Sbu1/2 conductor, and a D+/− conductor or cables where the voltage converted is from about 5 V, about 9 V, about 15 V or about 20 V, to up to about 48 V, or where the cables further comprise some or all of the circuitries in the Dongles described previously and/or PD Adapter described previously incorporated into the long communication cable to achieve the features of the external Dongles and/or PD Adapter.

### DETAILED DESCRIPTION

### Prior Art USB-C AOC Cable's Difficulty of Sending Remote Power and USB Bi-Directional Signals

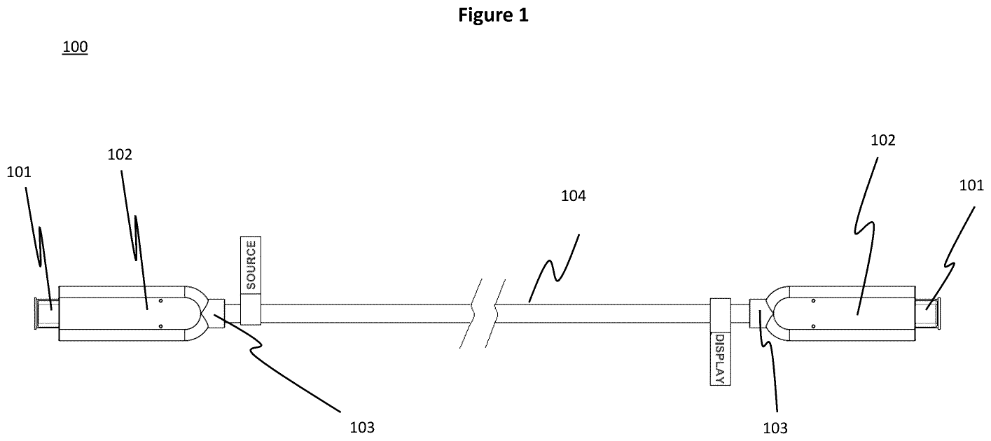

Referring to FIG. 1, shown schematically is a 2D view 100 of a prior art long USB-C cable 104 with male USB-C connector body 102 at each end, and front probe 101 at the front of the connector body; and a strain relief 103 at the rear of the connector body. The USB 3.2 cables have very high data rate of 5, 10 or 20 Gbps. For such high data rate USB cables longer than 5 m most likely will use fiber to send such high-speed data due to limits on transmission distance for standard copper USB cables. Once converted to light and sent through fiber optical strands, the signal can travel as far as 20 km without needing relays in between to boost the signal's transmission. However, there are other signals or functions that can't be or can't be easily sent by fiber, for example the USB 2.0 backwards compatible Tx/Rx signals (D+/D− pins) and the remote power signals (Vbus pins). The USB 2.0 signal is up to 480 Mbps and is bi-directional for differential signals. It would use 2 more fiber Tx/Rx components and fiber strands to send them by fiber and even if made it's still not true two-way communication. If sent by passive copper conductors, the signal becomes not usable after just a 10 to 15 m long cable. Also, to send 5 A, 20 V power over a USB-C cable, even with the thickest copper conductor used commercially in practice, the 18 AWG wire, will result in the resistance of the 2 wires becoming high. For example, for a 50 m long the resistance is (to and from): 0.021×50×2=2.1 ohm. The voltage-drop over these wires at 5 A current is 10.5 V which is undesirable. The 20 V of power from the power source would only have half the voltage left at the sink end which is also undesirable. So, it's a challenge in the field to extend the USB 3.2 cables to as long as 50 m with the USB 2.0 signals and/or the power delivery (PD).

Embodiments of the Current Invention: USB-C AOC Cable with Internal USB 2.0 and PD Circuits

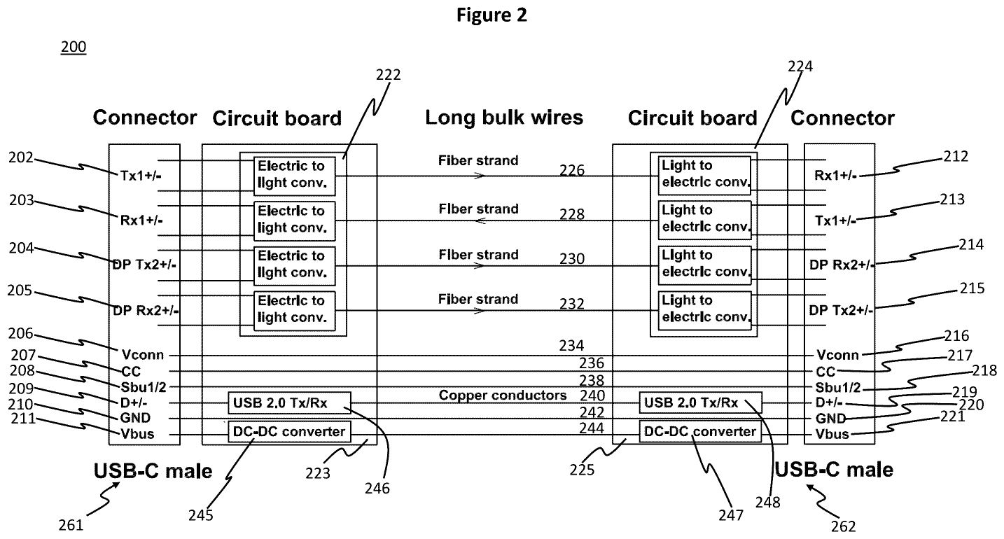

Referring to FIG. 2, shown schematically is an internal circuit block diagram view 200 of one embodiment of the current invention USB-C 3.2 AOC cable. Element 261 is one USB-C male connector at one end of the cable; 262 is another USB-C male connector at the other end of the cable. Elements 202 and 203 are pins for the USB 3.2 high speed data signal pair at one end of the cable; 212 and 213 are pins for the USB 3.2 high speed data signal pair at the other end of the cable. Elements 204 and 205 are pins for the (USB Alt mode) DP data signal pair at one end of the cable; 214 and 215 are the pins for the DP data signal pair at the other end of the cable. Elements 206 through 211 are the pins for Vconn, CC, SBU1/2, D+/−, GND and Vbus at one end of the cable, respectively. Elements 216 through 221 are the pins for Vconn, CC, SBU1/2, D+/−, GND and Vbus at the other end of the cable, respectively. Elements 222 is a fiber Tx IC that contains 4 electrical-to-light signal converter circuits. Element 224 is a fiber Rx IC that contains 4 light-to-electrical signal converter circuits. Elements 226, 228, 230, 232 are 4 fiber optic strands inside the long bulk wires of the cable connecting the fiber ICs 222 and 224. 234, 236, 238, 240, 242, 244 are the copper conductors inside the long bulk wires of the cable connecting the pins or through the circuits between the pins 206 through 211 at one end to the pins 216 through 221 at the other end of the cable. Element 246 is the USB 2.0 signal Tx/Rx IC at one end of the cable, 248 is the Tx/Rx IC at the other end of the cable. These Tx/Rx ICs 246 and 248 work as a pair, to change the USB 2.0 signal to a balanced signal form from balanced signal driver circuits, and also use AC coupling to cut off any ground potential differences between the devices connected at two ends of the cable, to amplify it to a higher amplitude (pre-equalization or pre-EQ) suited for long distance transmission at the Tx end, and change it back to the standard USB 2.0 signal. Element 245 is a DC-DC converter at one end of the cable, 247 is a DC-DC converter at the other end of the cable. Together these elements 245 and 247 change the standard DC voltage from the standard USB-C connectors 261 and 262's Vbus pins, convert to the proprietary voltage set by the manufacturer using embodiments of this design. In one embodiment, this internal DC voltage is selected at about 48 V, the highest DC voltage that is considered safe to use and sell with no requirement for UL certification. This 48 V internal voltage, is nearly 10 times the level of the most popular standard USB DC voltage of 5 V. Based on the formular P=U×I, for the same power P, when the voltage U is 10 times higher, the current I is 10 times smaller. This allows the USB-C long cable's bulk wire to use a much thinner copper conductor size to make the cable much smaller and softer, and cheaper to make representing a significant improvement.

Embodiments of the Current Invention: USB-C AOC Cable with External USB 2.0 and PD Circuits

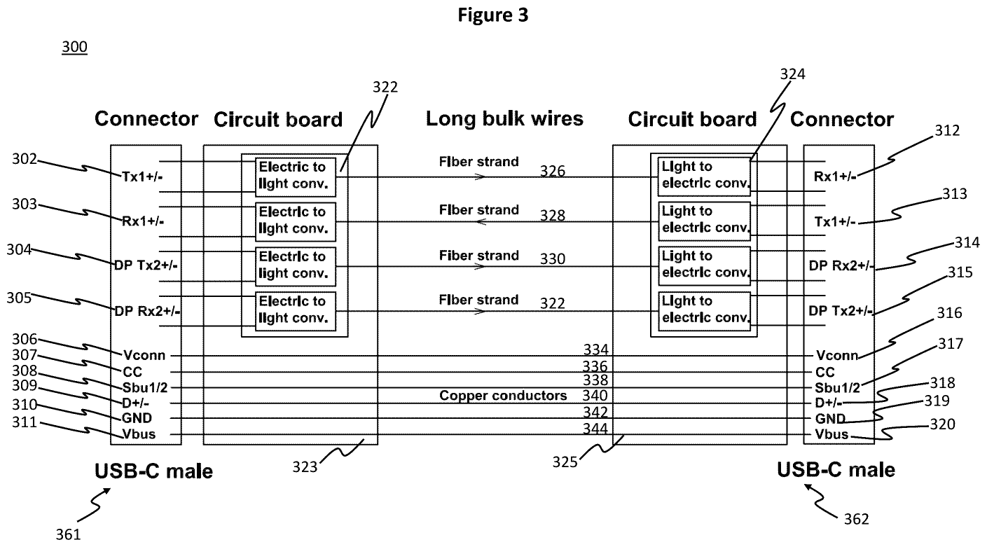

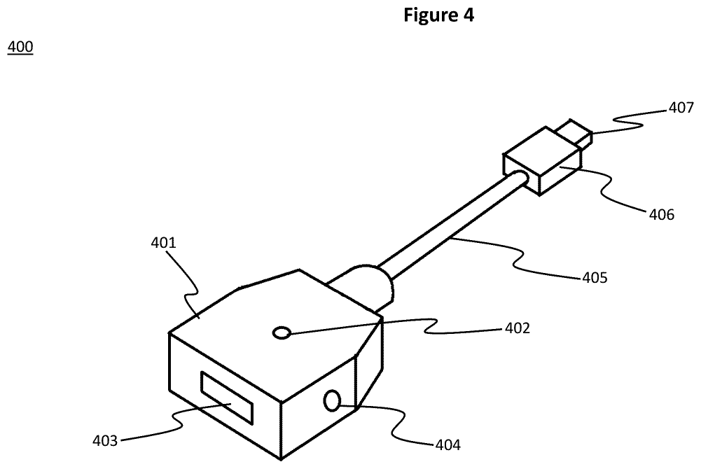

Referring to FIG. 3, shown schematically is an internal circuit block diagram view 300 of one embodiment of the current invention USB-C 3.2 AOC cable. This cable is basically the same as the cable 200 shown in the FIG. 2, except the USB 2.0 circuit components 246 and 248, and PD circuit components 245 and 247 are now removed from this cable and placed into a pair of external Dongles 400 that will be described in FIG. 4 in the paragraph after this one. There are several advantages by moving these two circuits to a pair of external Dongles: 1) The USB-C AOC cable's plug body size can be dramatically reduced; 2) The USB-C AOC cable's cost can be significantly reduced for the certain embodiments for sale to groups of users who do not need the USB 2.0 backwards compatibility and/or the PD functions in their applications; 3). By making a pair of external Dongles available, the other general purpose USB AOC cables that were not designed the USB 2.0 or PD in mind or can't send the USB 2.0 and PD to over a long cable length such as for long USB AOC cables that are typically found permanently sealed inside the various business or other building walls or ceilings during the construction that are not compatible with USB 2.0 or PD, such USB AOC cables can now be retrofitted to be compatible with USB 2.0 and/or PD without the need to tear open the walls or ceilings to replace the cables inside. All the components in the embodiments shown in FIG. 3 serve the same functions as the components in the FIG. 2 with the same item number minus 100, respectively. So, there's no need to repeat the descriptions of the components here in FIG. 3.

### Embodiments of the Current Invention: USB-C Dongles

Referring to FIG. 4, shown schematically is an external 3D view 400 of one embodiment of the current invention USB-C 3.2 Dongle. The Dongle has a body 401 with its female receptacle 403 for accepting the USB-C AOC cables male plug 361 or 362 as shown in FIG. 3. A short cable 405 and a male USB-C connector 406 and its male probe 407 are shown. The Dongle body 401 also has an optional female receptacle connector 404 to receive external power source if needed, and an optional female threaded screw nut 402 for accepting a security locking screw. The Dongles are used in a pair, one plugged on each end of the cable 300 shown in FIG. 3 to provide USB 2.0 and/or PD functions to the USB-C 3.2 cable that don't have these functions if such functions do not work in such long length of the cable. The Dongle can be made as multiple embodiments; one of embodiment has both the USB 2.0 and PD circuits; another embodiment only has the USB 2.0 circuits; and yet another embodiment only has the PD circuits. This would offer different options and price points for commercial embodiments for the users to choose and pay for the functions they need to use.

### Embodiments of the Current Invention: USB-C Dongle Internal Circuit Block Diagram

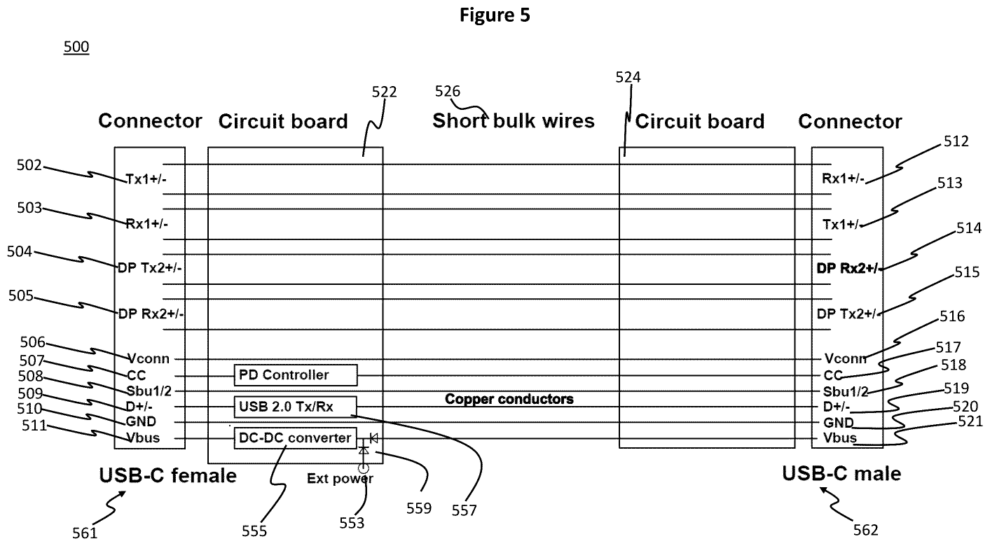

Referring to FIG. 5, shown schematically is an internal circuit block diagram view 500 of one embodiment of the current invention USB-C Dongle. The Dongle has a female USB-C receptacle connector 561 at one end, and a male USB-C plug connector 562 at the other end. All the pins 502, 503, 504, 505, 506, 507, 508, and 510 in the connector 561 connect directly one by one to the pins 512, 513, 514, 515, 516, 517, 518 and 520 in the connector 562 at the other end via short conductors in the short bulk wire 526, respectively. Pins 509 from connector 561 are connected to the USB 2.0 Tx/Rx circuit 557 on the PCB 522 inside the Dongle body. These Tx/Rx ICs 557 inside two Dongles one at each end of the USB-C AOC cable work as a pair, to change the USB 2.0 signal to a differential (balanced) signal form, and modulate the signal when needed. Pins 511 from connector 561 are connected to the DC-DC converter circuit 555 on the PCB 522 inside the Dongle body. The optional female connector 553 for the external power is connected to the DC-DC converter circuit 555 via an “OR” circuit 559 to be combined with the internal power from the pin 512 of the connector 562. This “OR” circuit only allows the power source with the higher voltage between the power from connector 553 and the pin 521 from the connector 562 to go through to the DC-DC converter circuit 555 while cut off the lower voltage power source. Although this one embodiment of the OR circuit 559 shown here is achieved by two diodes; other embodiments known by a skilled engineer of circuits that can achieve the same OR functionality of allowing power source with higher voltage to go through while the power source of lower voltage is cut off are all alternate embodiments covered by this disclosure. For example, the OR circuit can be achieved by multiple diodes, or multiple transistors, or multiple gates in IC chips. The external power source and OR circuit are just one embodiment of this optional function. In Dongle embodiments the DC-DC converter converts the incoming about 5 V, about 9 V, about 15 V or about 20 V to about 48 V. Although this one embodiment shows both the USB 2.0 Tx/Rx and the DC-DC converter for PD, other embodiments can be with only the USB 2.0 Tx/Rx circuit or with only the DC-DC converter circuit for PD. All of these iterations represent alternative embodiments covered by this disclosure.

### Embodiments of the Current Invention: USB-C Locking Sleeve

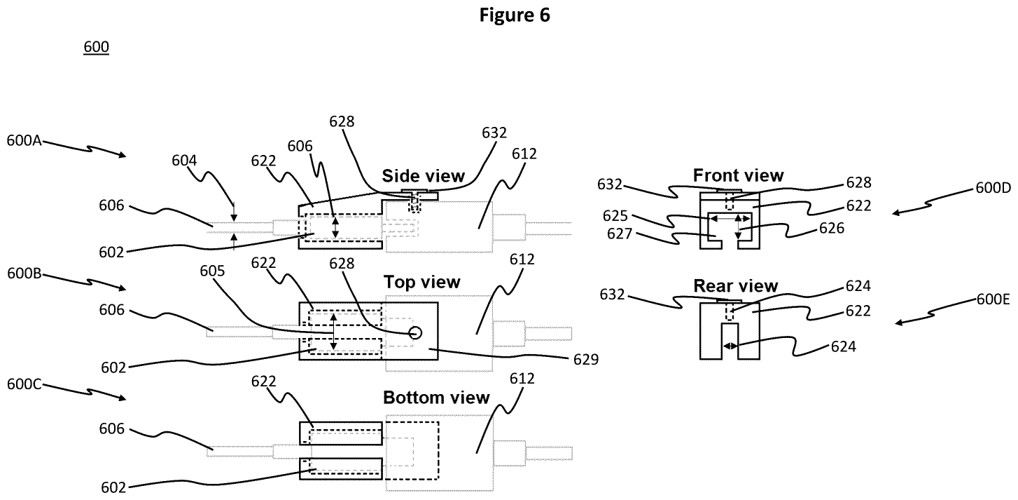

Referring to FIG. 6, shown schematically is a one embodiment of the current invention USB-C Locking Sleeve 600 inside view 600A, top view 600B, bottom view 600C, front view 600D, rear view 600E, in which all components in black lines belong to this Locking Sleeve. The other components shown by gray lines belong to other objects: a male USB-C plug 602 from a USB-C AOC cable described in paragraph [0028] to [0029], and a USB-C body 612 from a USB-C Dongle described in paragraph [0030] to [0031]. The male USB-C plug 602 from a USB-C AOC cable is plugged in into the female receptible of a USB-C body 612 of a USB-C Dongle. The Locking Sleeve's bottom and rear small opening width 624 is slightly wider than the USB-C AOC cable bulk wire 606's OD (overall diameter) 604; thus, the opening can let the bulk wire slide in. The Locking Sleeve's middle and front opening width 625 is slightly wider than the USB-C AOC cable male plug 602's body width 605; and the height 626 slightly higher than 606; thus, the plug 602 can slide into the inner chamber 627 of the Locking Sleeve. The Locking Sleeve also has a long and wide Flap 629 with a screw hole 628 in the center front. Once the USB-C AOC cable's male plug 602 is inserted into the female receptacle of the Dongle body 612, the user can first slide down the Locking Sleeve 622 over the USB-C AOC cable's bulk wire 606, then slide forward towards the male plug 602 until the whole male plug's body 602 is inside the Locking Sleeve 622's inner chamber 627, while the Flap 629 is over a portion of the Dongle body 612 and the screw hole 628 is aligned with the female screw nut 402 on the Dongle body 401 in FIG. 4. A security screw 632 then can be threaded into the nut 402 to form a permanent lock between the USB-C AOC cable's male plug 602 and the Dongle body 612. There are two main purposes of this secure lock: 1) to prevent the USB-C AOC plug 602 becoming loose from the Dongle body 612 during usage like in a presentation such as a live PowerPoint presentation; 2) to prevent the Dongle being removed or stolen from the conference room since it's a rather small piece and easily detachable from the USB-C AOC cable if no Locking Sleeve is in place.

Prior Art Active PCB with Metal Shielding and Open Holes for LEDs

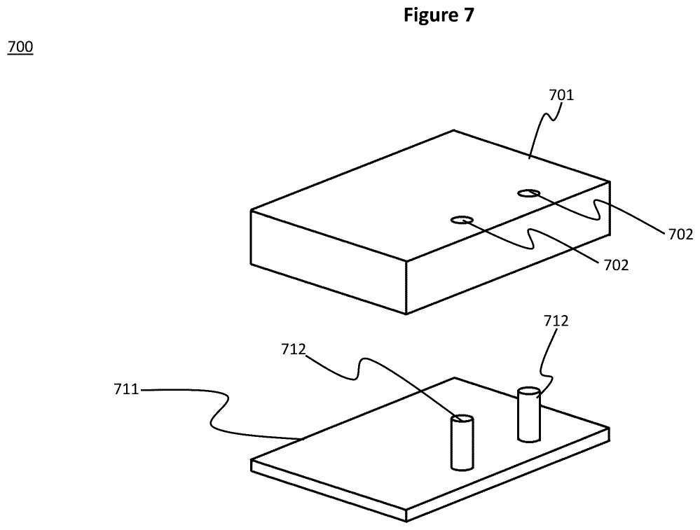

Referring to FIG. 7, shown schematically is a 3D view 700 of a prior art active circuit PCB 711 with LEDs 712, and a thin metal shield shell 701 with open holes 702 to let the lights from the LEDs 712 to come out and be visible to the users. The thin metal shield 701 designed and manufactured to form a 6 sides air tight shell to wrap all components and circuits inside thus to prevent the EMI leaking from the inside circuits to the outside environment; and also, to prevent the EMI from outside environment leaking into the inside circuits causing distortion or interference. However, in embodiments with LEDs as indictors, the metal shell must have small opening windows to let the LED lights to come out for indications. These small opening windows defeated the shielding purpose, allowing the EMI to leak in and out through those small opening windows which is undesirable.

Embodiments of the Current Invention: Complete EMI Shielding while Still Allowing the LED Lights to be Visualized

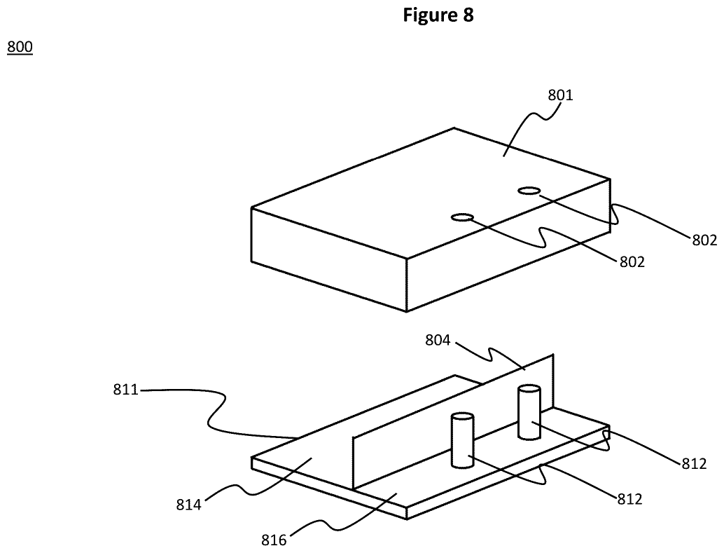

Referring to FIG. 8, shown schematically 800 is one embodiment of the current invention active circuit PCB 811 with LEDs 812, and a thin metal shield shell 801 with open holes 802 to let the light from the LEDs 812 to come out and be visible to the users and an indicator of status, similar to the layout in FIG. 7. The difference in this embodiment is that all the components for the circuits that process the high frequency signals like USB, HDMI, DP, and others, are placed on one section 814 of the PCB 811 while the components of the circuits that process the DC signals like the LED indication are placed on the other section 816 of the PCB 811. Then a thin metal divider wall 804 is placed between the section 814 and 816 of the PCB 811; and this divider wall 804 touches the inner surface of the thin metal shield shell 801 along all edges so that they touch each other; thus, the left half of the thin metal shield shell 801 and the thin metal divider wall 804 now form an air tight metal chamber with the desired 6 sides for effective EMI shielding. The sealed 6-sided section is thus completely EMI shielded with shells surrounding section 814 of the PCB that does not allow any EMI interferences leaking between the PCB 811 and outside environment. The right half of the thin metal shell 801 and the divide wall 804 also form another metal chamber which is not air tight due to the openings 802 for the LED lights to come out; but it does not matter because the circuits in this half of the PCB only handles DC signals that has no EMI emissions to the outside environment; and is also immune to the EMI interferences from the outside environment because the DC circuit does not react to high frequency EMI signals. Embodiments of this invention allow the LED indication to function while still maintained the full and effective EMI shielding. The embodiment shown schematically in FIG. 8 is only one of many embodiments a skilled engineer can envision and make for this invention. The PCB shape can be rectangular, square, round or any shapes or dimensions, like 5×3 cm, 4×2 cm, 6×3 cm etc; the outside metal shield shell can be cubical, round, or any other shapes; the divider wall can be straight, curved, bent or any other shapes; the divided sections of the PCB can be 2, 3, 4 or any numbers of the sections; the materials for the outside metal shield can be copper, tin, aluminum or any other metals; can be thin shell, metal foil sheets or any other materials. These are all alternate embodiments within the scope and purpose of this invention.

Prior Art Bulk Wires with High Capacitance for Communication Lines

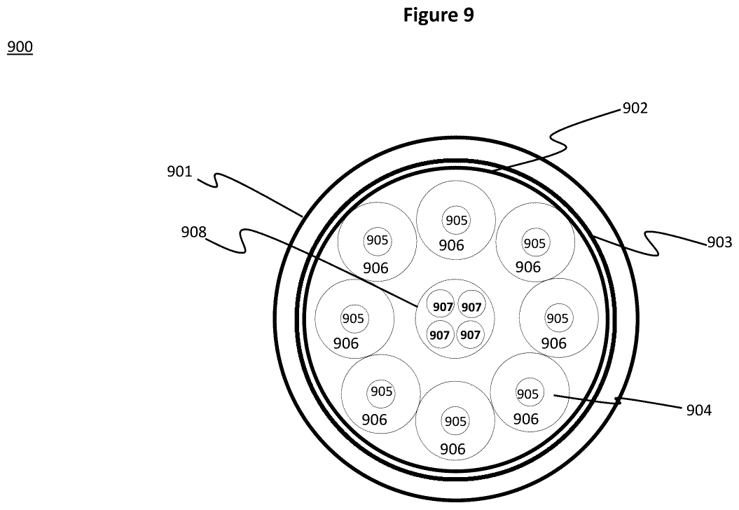

Referring to FIG. 9, shown schematically is a cross section view 900 of a prior art USB AOC bulk wire. This prior art wire has 4 fiber strands 907 wrapped by a non-conductive thin material like paper or PVC sheet to form the center fiber bundle 908. Several copper conductors 905, each wrapped by its insulation layer 906, form the insulated conductors 904, laid evenly outside the center fiber bundle 908. All these copper conductors 905 and center fiber bundle 908 are wrapped by a non-conductive thin material like paper or PVC sheet to form the bulk wire core; then they are wrapped by a layer or more conductive materials 903 like aluminum braiding and/or foil sheet to form an overall shielding layer to prevent the internal EMI from emitting out and also to prevent outside EMI from getting in. Then an overall wire jacket 901 wraps all other components inside to provide protection. A skilled engineer will notice that the distance between the conductors 905 and the overall conductive shielding layer 903 is as small as it can be with only a very thin conductor insulation 906 of about 0.1, or 0.15, 0.2 mm etc. and the overall wrapping sheet 902 in between. The capacitance between the conductor 905 and the overall shielding 903 is in reverse proportional with the distance between them. Now with the distance between them as small as possible in this design, the capacitance is as high as it can be between them. The amount of time of signal delay is determined by τ=RC where the R is the line impedance and the C is the line capacitance. Often the impedance R is defined by the technical standard like HDMI or USB and is a fixed number. This prior art design in FIG. 9 makes the C as big as it can be, thus the t is as big as it can be. This would prevent the timing sensitive communications like the popular I2C (the Inter-Integrated Circuit protocol) not working properly. Also, the cut off frequency of a RC system is: f=1/(2πRC); again, higher the capacitance, lower the max frequency the system can send. Again, this prior art design in FIG. 9 would limit the bandwidth of a communication sent through the cables made of this bulk wire. Also, the capacitance C is proportional with the length of the cable; longer the length, bigger the capacitance. So, this design would create more time delays or limit more bandwidth with longer cables which is undesirable.

### Embodiments of the Current Invention: Reduced Capacitance AOC Bulk Wires

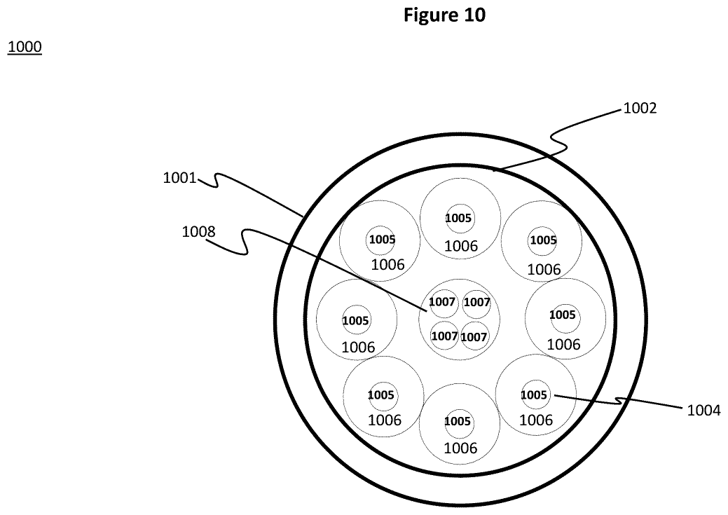

Referring to FIG. 10, shown schematically is one example embodiment of the current invention Active Optical Cable (AOC) bulk wire 1001 cross section view 1000. Similar to the bulk wire construction described in for FIG. 9, the 4 fiber strands 1007 are wrapped by thin non-conductive sheet to form a fiber core 1008; several copper conductors 1005 each is wrapped by non-conductive insulation layer 1006 to form insulated conductors 1004, then these conductors are laid around the fiber core 1008. All these components are wrapped by non-conductive 1002 material and then the overall jacket 1001. The difference is the lack of the overall conductive shielding layer 903 in FIG. 9. This is achieved by adding a balanced signal driver circuit using differential balanced signaling in the USB 2.0 signals through the conductors connecting the D+ and D− pins described in [0022] and [0036] to [0039]. In other embodiments the differential balanced signaling can be included for conducting connectors for the CC for USB data signal handshaking and Sbu1/2 lines for DP signal handshaking. This balanced signal driver circuit format reduced the emissions from this USB 2.0 signal conductor pairs to the outside environment to the minimum; it also reduced the outside EMI interferences to these pair of USB 2.0 conductors to the minimum because the interferences is canceled out at the far end with the receiving circuit only receive the differences in signals between these 2 conductors. The much higher frequency signals for the USB 3.2 data are converted to light and sent through the fiber strands 1007. This embodiment cable gives no EMI emission concerns. The rest of the conductors connecting the Vbus pins of the USB-C connectors are DC power, and also have no EMI emission concerns either. Embodiment cables with these designs for this current invention allow the bulk wire 1001 to meet the EMI regulations without the need for an overall shield layer 903 as shown in the prior art cable described in [0043]. This means the distance between the conductors 1005 and the overall shield which does not exist in this current invention bulk wire design is very far apart, thus the capacitance between them is reduced to as small as possible representing a significant improvement. Embodiment cables in real tests reduced the capacitance between the electrical lines connected to the conductors 1005 to system ground by up to 10 times. Thus, the system communication time delay is reduced by up to 10 times, and the maximum possible communication bandwidth is increased by up to 10 times all of which solve problems for transmitting such signals over USB-C cables.

### Embodiments of the Current Invention: Inner Power Circuits Inside a Long Cable Comprising Long Distance DC Converter Circuitry

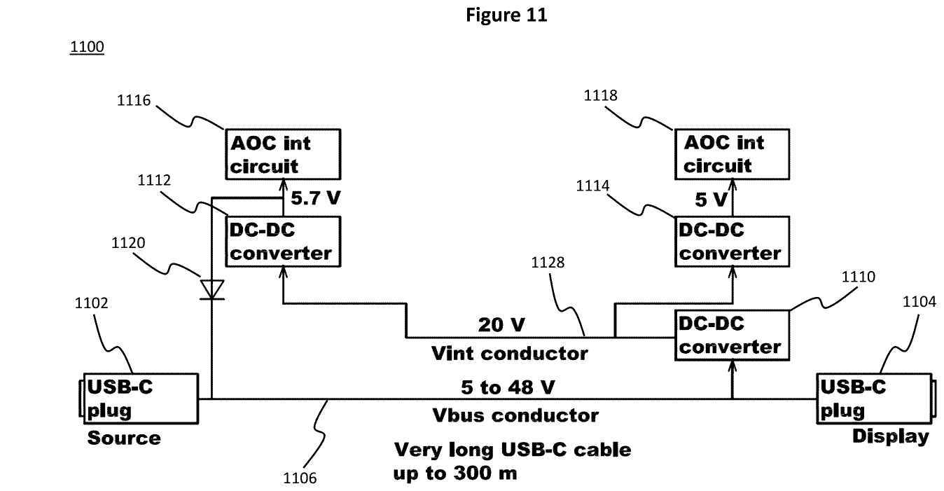

Referring to FIG. 11, shown schematically is a circuit block diagram view 1100 of one embodiment of the current invention comprising inner power circuits inside a long USB-C cable. A male USB-C plug 1102 in the Source end and a male USB-C plug 1104 on the Display end are connected by bulk wires including the Vbus conductor 1106 and the new invention Vint conductor 1128. At least one DC-DC converter circuit blocks form a preferred embodiment for USB-C with additions of new elements not part of current USB-C specifications and other cable formats to achieve the purpose of regulating current via higher voltage to achieve long cable length power transmission. This DC-DC converter circuitry can be scaled from 1, to 2, 3 4, 5, 6, 7, 8, 9, or 10 or more DC-DC converter circuits in different embodiments and is referred to herein as “Long Distance DC Converter Circuitry”. In a preferred exemplary embodiment, a first DC-DC converter 1110 gets the DC voltage from the Vbus line (shown as 5 to 48 V) from the Display end, converts it to an internal DC voltage, in one embodiment shown in this figure as 20 V. This higher voltage than the original 5 V can transmit current over long distances from display to source device with relatively small losses resulting in functional source display recognition or handshake for functional signaling. For example, if the Display device would send 5 V power over a long 50 m cable and only about 3 V would reach the source device which is not enough. Elevating the voltage to, for example, 20 V with the other regulatory DC-DC circuits solves this long-distance transmission problem because for the sample power, higher the voltage, lower the current, and thus lower the power lost along the long cable. Another, or second DC-DC converter 1114 converts this internal DC voltage to the voltage that the cable's inner circuits in the Source end requires, in one embodiment shown in this figure as 5 V. In other embodiments these DC-DC converters convert the incoming about 5 V, about 9 V, about 15 V or about 20 V etc., to about 10 V, 15 V, 20 V, 24 V, 30V, 36 V, or 48 V or other voltages then convert back to about 5 V, 9 V, 20 V, 30V, 24V, 36V, or 48V or other voltages. A skilled engineer would recognize depending on needs the voltages and DC-DC converters could be scaled to any voltage or difference required in different embodiments. This voltage from the output of the DC-DC converter 1114 then feeds the inner AOC circuits 1118. It is understood that AOC circuits require lower voltages of about 5 V or thereabouts for example for commercial consumer electronics. The inner DC voltage shown in one embodiment as 20 V in this figure is also sent to the far end (Source end) of this long cable via the Vint conductor 1128, and is then fed to another DC-DC converter 1112 at the Source end. The Vint conductor is new and represents embodiments of the current invention and is not part of current USC-C cable and connector specifications (USB Implementers Forum, Inc.). This additional or third DC-DC converter 1112 converts the inner DC voltage from conductor Vbus to the voltage that the cable inner circuits in the Source end requires, in one embodiment shown in this figure as 5 V. This voltage from the output of DC-DC converter 1112 then feeds 2 circuits: 1) the inner AOC circuits 1116; 2) the circuits in the external Source device that connected to the cable via the male USB-C plug 1102 via a diode 1120 or equivalent component or circuit that can cut off this connection when the Vbus 1106 voltage is higher than this voltage from the output of the DC-DC converter 1112.

Advantages for Long Distance DC Converter Circuitry for the embodiment set forth in FIG. 11 include but are not limited to 1) the ability to power the internal AOC circuitry at the Source and Display ends of long cables, 2) the ability to charge an external source device (i.e., lap top), and 3) allowing the choice of thin flexible conductors for the related wires about 16 times smaller than old design given the voltage is 4 times higher (20 V/5 V) and the current is 4 times smaller. In other embodiments the Long-Distance DC-DC Converter Circuitry can have the same advantages and be for larger power requirements incrementally from 20V to 48V for example where there may be demand for larger power requirements for charging or other applications. In such embodiment cables, conductors would be able to handle the increased power, and increased costs for manufacturing would be expected.

The inner power circuits' direction for feeding power, the inner DC voltages, the circuits that achieve the same function as the diode 1120, the forms of the DC-DC converter circuits 1110, 1114, 1112, the inner AOC circuits 1116 and 1118 is shown in this FIG. 11 are just some of the example embodiments of this invention.

For example, USB or HDMI or DP or other cables or connected devices would use a similar Long Distance DC Converter circuitry configuration or alternately utilize at least 1, 2, 3, 4, 5, 6, 7, 8, 9, or 10 or more DC-DC converter circuits in different applications. Commercial applications include but are not limited to video devices, internet devices, medical devices etc. Specific Long Distance DC Converter Circuitry block diagrams comprise any forms of circuits that convert the DC voltage to a different DC voltage that can be used for long cable power transmissions. In other embodiments the DC-DC converter converts the incoming about 5 V, about 9 V, about 15 V or about 20 V to about 48 V. Other similar inner power circuits, voltages, circuit forms, functions of the circuits being fed with this inner power circuits (for example the 1116 and 1118) instead of AOC circuits, they can be active cable circuits, MCU (micro controller units), other type of cables other than USB-C, include but not limited to HDMI, DP, Lightning, Ethernet cables, should all be considered as embodiments of this invention and covered by this patent application.

### Embodiments of the Current Invention: Inner Vbus Line Switch Inside a Long Cable Compromising Legacy Upgrading Circuitry

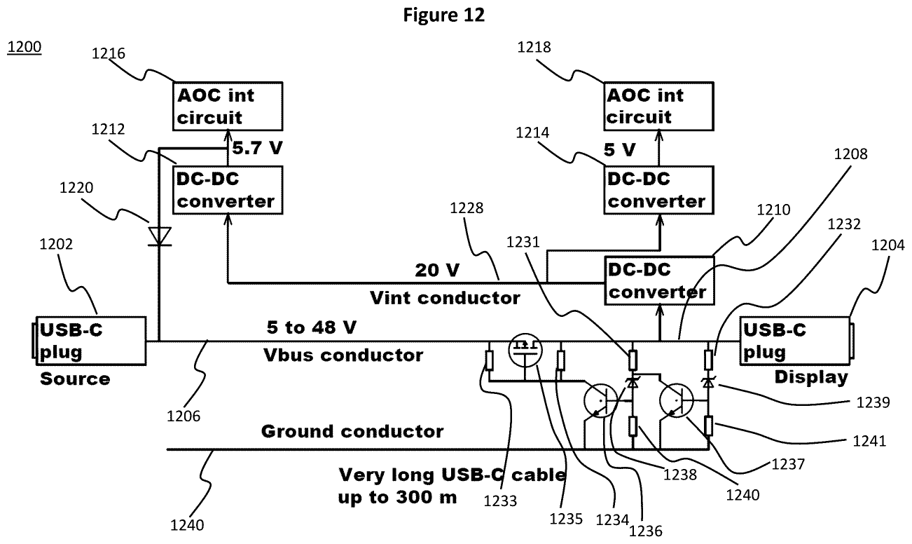

Referring to FIG. 12, shown schematically is a circuit block diagram view 1200 of one embodiment of the current invention inner Vbus switch circuits inside a long USB-C cable. In this embodiment circuitry represented by 1235, 1231, 1208, 1233, 1234, 1236, 1237, 1238, 1239 (collectively, the Legacy Upgrading Circuitry) represent a Legacy Upgrading Circuitry embodiment for use with legacy USB format Source devices (e.g., USB 2.x, and so on) before USB 3.x to let the Display to send larger power than the source device needed to compensate the power loss on the long cable. Here, the Deception Upgrading Circuitry tells the Display device the Source device is a USB 3.x device and not a legacy USB 2.x or earlier device. This allows the Source to ask for, and the Display to send more power in when used in conjunction with the Long-Distance DC Converter Circuitry, it effectively solves the long-distance signal transmission problem for older legacy devices.

In the FIG. 12 embodiment, a male USB-C plug 1202 in the Source end and a male USB-C plug 1204 on the Display end are connected by bulk wires including the Vbus conductor 1206, ground conductor 1240, and Vint inner power conductor 1228. The Source end Vbus conductor 1206 and the Display end of the Vbus conductor 1208 is connected by a MOSFET 1235 whose gate pin is fed by DC bias via a resister 1233 from the Source end and another resister 1234 from the Display end to keep the MOSFET 1235 conductive in most conditions. One transistor's 1237 base pin is fed by a resister 1232 via a Zener diode 1239. Another transistor 1236's base pin is fed by a resister 1231 via a Zener diode 1238, and also controlled by the transistor 1237's collector. This transistor 1236's collector pin controls the MOSFET 1235's base pin. The breakdown voltage of the Zener 1238 is chosen to be lower than the breakdown voltage of the Zener 1239; thus, when the voltage of the Display end Vbus conductor 1208 is lower than the Zener 1238's voltage or higher than the Zener 1239's voltage, transistor 1236 is open, and the MOSFET 1235 is conducting, the two sides of the Vbus line 1206 and 1208 are conducted together as one conductor. This condition ensures the initial recognition or hand shaking between devices can be conducted successfully. Only when the voltage of the Display end Vbus conductor 1208 is in between the voltages of the Zener 1238 and 1239, the transistor 1236 conducts, and cutting off or kills the MOSFET 1235's Gate voltage and make the MOSFET open, thus cutting off the connections between the Vbus line's Source end 1206 and Display end 1208. This allows the long cable to get a Vbus voltage from the Display end and to feed the Source end with a different voltage after the hand shaking period together with the PD Adapter's communications via the CC line. Although the embodiments shown in FIG. 12 uses MOSFET for switch, transistors for control, Zener diodes for voltage definition, 18 V and 22 V as examples, any components, component values, circuits that achieve the similar functions as shown in FIG. 12 and described in the patent application should all be considered the embodiments of this invention and all covered by this patent application. For example, HDMI, DP, Ethernet cable etc. would use a similar Legacy Upgrading Circuitry in different applications including but not limited to long distance power sending. Commercial applications include but are not limited to HDMI remote powering connected device, Ethernet remote powering connected device, medical special cable powering connected device etc, specific Legacy Upgrading Circuitry block diagrams comprise DC-DC converter or similar circuits that changes the DC voltage for long cable power sending.

### Embodiments of the Current Invention: PD Adapter Pigtail

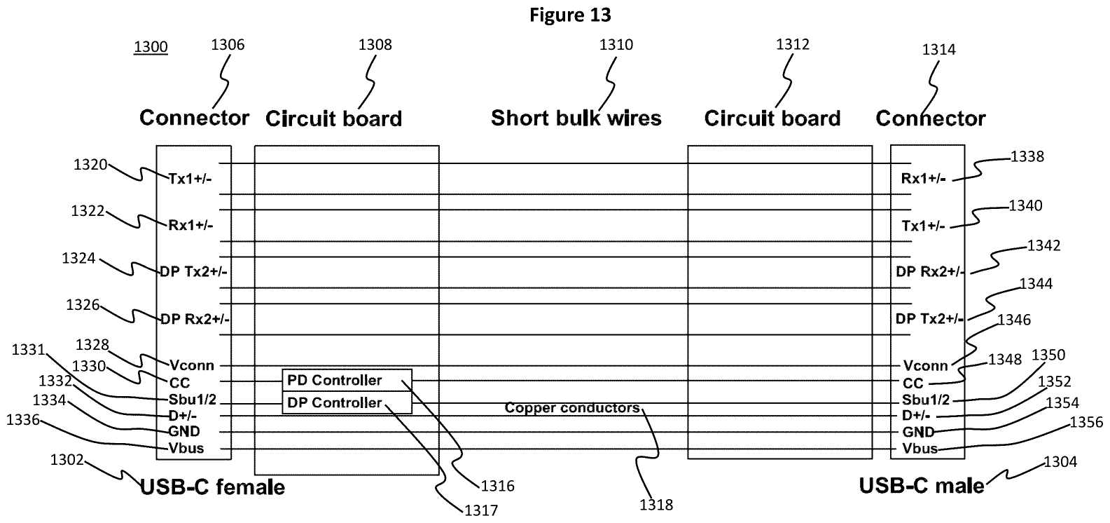

Referring to FIG. 13, shown schematically is a circuit block diagram view 1300 of one embodiment of the current invention PD Adapter. In this embodiment, the PD Adapter has a female USB-C connector 1306 and a male USB-C connector 1314 with short bulk wires 1310 connected in between. This embodiment can be an exemplary short pigtail cable of about 10 cm (about 4 inches) or thereabout to be added between the long active optical fiber cable and the source or display device serving as a patch for different incompatibility scenarios that are commonly encountered. Inside the plug body of the female USB-C connector 1306, there's a printed circuit board (PCB) 1308. The PCB 1308, comprises circuits that contain a PD Controller IC 1316 and its supporting components, as well as the firmware loaded inside the IC 1316 which is essentially a central processing unit (CPU). This PD Controller 1316 connects and communicates with the USB-C device connected to the female end connector 1306 via the CC line pin 1330. This PD Controller 1316 also connects and communicates with the USB-C device connected to the male end connector 1314 via the CC line pin 1348. This prevents the device connected to the female end connector 1306 from directly communicating with the device connected to the male end connector 1314, and allows the PD Controller to communicate with the two devices separately with different parameters. The communication flexibility with different parameters for the Source and Display allows the PD Adapter to correct or fix many different types of incompatibility issues that arise when any 2 devices such as any Source and Display are connected directly with long or very long cables. In one example embodiment, if the Display device does not read the E-marker request from a long USB-C cable for a 5 V on the Vbus line, and sends 20 V instead that cause the system into endless power on and off cycles, adding this PD Adapter in between can force the Display device to send the 5 V on the Vbus line to make the system working. In another example embodiment, if the Display device sends one voltage on the near end, and the Source device receives a lower voltage on the Vbus line and reports this to the Display device as an error, the system enters into endless power on and off recycle, adding this PD Adapter in between can allow the PD Adapter to communicate with the Source and Display devices separately to resolve this conflict. In another example, the optional DP Controller 1317 micro controller IC in between the input and output of this adapter to manage the number of USB-C signal lanes to be used for DP video. Additionally, firmware and updates represent additional embodiments in combination with the aforementioned circuitry and components. In all such embodiments the PD Adapter's firmware can by updated after sales and being installed in the customer's site over time, so when the manufacturer discovered the new incompatibility issues and developed fixes it can issue firmware updates worldwide to update the PD Adapters in use to address these new incompatibility issues. Although this FIG. 13 only shows this embodiment of the PD Adapter as a short pigtail with a female connector at one end and a male connector at the other end, all other embodiments including but not limited to the same circuits inside a long cable, or inside a source device, or inside a display device, should all be covered by this patent application. Although this patent application listed 2 of the potential USB-C system incompatibility issues and the fixes by adding the PD Adapter, there are many other issues that caused by the USB specifications lacking of definitions for long cables or by the device manufacturers' lack of design considerations for systems with long cables, which can be fixed by adding more firmware conditions and fixes to the PD Adapter sitting in between devices and communicating with devices in separately in different parameters that allowed by this invention, and they should all be covered by this patent application. Fixing such incompatibility scenarios are represented by the following embodiments including but not limited to 1) Read connected USB-C cable's E-marker IC's brand and product IDs; 2) If it's a known long AOC cable, request the Display device to send 5 V to Vbus, and tell Source device to accept 5 V; 3) If it's a known short AOC or active cable, change CC data to make the system working; 4) If the Source device is a camera requesting 5 V 0.9 A, then change that request to 5 V 1.5 A (or other highest amp setting the display can offer at 5 V) and send that altered request to the display; 5) The other functions maybe added once we know more incompatibility issues in the future

What is claimed is:

1. A communication cable comprising:
a cable having at least a first end and second end and at least one jacket;
a plurality of conductors placed within the cable;
at least two connectors, wherein a connector is attached at first end and a second end of the cable;
at least one printed circuit board configured within or near the end of each of the at least two connectors, or wherein the printed circuit board is disposed in or near the middle of the cable, wherein each of the printed circuit boards further comprises the first set of circuits, or the second set of circuits or both sets of circuits or subset of circuits of each of a first set of circuits and/or second set of circuits,
the first set of circuits further comprising:
at least one balanced signal driver circuit, to reduce the emissions from at least one signal conductor pair to the outside environment and also to reduce outside EMI interferences with the signal in the at least one signal conductor pair;
at least one AC (Alternating Current) coupling capacitor to cut off the large ground potential differences between devices connected to the at least one connector of the cable;
a signal transmitter (Tx) circuit in one of the printed circuit boards that converts the data signal into a balanced signal for long distance transmission,
a signal receiver (Rx) circuit in one of the printed circuit boards of the cable that converts the balanced signal back to the original signal format;
the second set of circuits comprising:
a first DC (Direct Current) to DC converter configured in at least one of the printed circuit boards that changes the DC power voltage to up to multiple times higher, to send through the conductors inside the cable from one end to the other end;
a second DC-DC converter in at least one of the printed circuit boards that converts the power voltage either to the same voltage that is disposed into the near end of the cable or to a voltage set by the user for the devices connected an end of the cable.

2. The communication cable of claim 1:
further comprising one or more fiber channels, wherein the cable is a USB-C 3.2 AOC (Active Optical Cable),
and/or the USB 3.2 signals and/or DP (DisplayPort) signals are sent through the fiber optics channels,
and/or the legacy USB 2.0 signals is sent through the balanced signal driver circuit with optional AC coupling;
and/or the DC-DC converter converts the incoming about 5 V, about 9 V, about 15 V or about 20 V to up to about 48 V, and sends the voltage through the long cable; then converts the voltage back to the same voltage as the incoming power, or to a voltage set by the user.

3. A pair of communication cable Dongles system comprising:
a first and second Dongle each comprising a cable with a first end and second end for transmission of digital signals;
each Dongle further comprising:
a Dongle body;
a first and second connector;
wherein the first or second Dongle or both Dongles have the first connector configured for the cable to plug into the first connector;
a second or a third short cable configured on one end of the first or second or each Dongle body or both Dongle bodies;
a second connector at the end of each of the second or third short cable from the first or second or both Dongle bodies is configured to plug into a device outside this Dongles system; wherein each Dongle has at least one printed circuit board, each Dongle's printed circuit board further comprises at least one of the following sets of circuits:
a first DC-DC converter circuit at the first or second end of the first cable, wherein the DC-to-DC converter circuit increases the DC power voltage to up to multiple times higher than the incoming DC power voltage, and wherein the voltage changed DC power is sent through the power conductors inside the cable to the other end;
a second DC-DC converter circuit, wherein the second DC-DC converter circuit is configured inside the first or second Dongle, wherein the first or second Dongle is connected to the other end of the first cable, and wherein the second DC-DC converter circuit converts the power voltage either to the same voltage that comes in into the first end of the first cable or to a voltage set by the user for devices connected to this second Dongle; and
an optional PD Controller that connects in between the external device and the long cable via the communication line, to allow the long cable to have different power voltage inside the long cable from the inner power voltage from the connected device; and also allow the PD Controller to fix different incompatibility issues via the communication line;
an optional signal driver circuit comprising a coupling capacitor wherein the single driver circuit converts the data signal into a balanced signal for long distance transmission, and the coupling capacitor uses AC current to cut off the large ground potential differences between devices connected to the first and second ends of the first cable;
an optional signal receiver circuit inside the first or second Dongle connected to the first or second end of the cable, wherein the single receiver circuit converts the balanced signal back to the original signal format.

4. The pair of communication Dongles of claim 3, wherein the connector configured at the Dongle body is a female USB-C connector; and the connector configured at the other end of the short second or the third cable that connected to the first or second Dongle body is a male USB-C connector;
and wherein the first cable is a USB-C 3.2 AOC cable further comprises;
one or more fiber channels, the USB 3.2 data signals and/or DP (DisplayPort) video signals are sent through the fiber optical channels,
and/or one or more copper conductors, the legacy USB 2.0 signals is sent through the balanced signal driver circuit with AC coupling converted inside the Dongles via the copper conductors of the first cable;
and/or the DC-DC converter converts the incoming about 5 V, about 9 V, about 15 V or about 20 V to up to about 48 V inside one Dongle, and converts to the same voltage as the incoming voltage or a voltage set by the user inside the other Dongle.

5. The communicate cable in claim 1 and claim 2, where the cable is selected from the group consisting of USB, HDMI, DP, SDI, IEEE 1394, Thunderbolt, Lighting cables, or other formats, or mixtures thereof.

6. A Locking Sleeve comprising:
a chamber with a first opening in the front that can allow a connector body of a male connector of a cable to slide in;
an open slot on the bottom of the chamber configured to allow a bulk wire of a cable to side up into the chamber;
a flap connected to the top of the chamber and extended forward to the front of the chamber of the sleeve;
the flap further comprising
a hole on the front portion of the flap configured to allow a security screw to go over from the top down;
when the cable's connector is plugged into the connector on a Cable Accessory's main body, the Locking Sleeve can be slide down onto the cable's bulk wire portion away from the male connector body, then slide forward until it wraps around the male connector body, and its Flap goes over to the top portion of the Cable Accessory's main body, then a security screw can be screwed down through the Flap into the female screw hole in the Cable Accessory's main body, to form a permanent lock between the cable's male plug and the Cable Accessory.

7. The bulk wires used in cable in claim 1, wherein the conductors for communication are laid inside the jacket of the bulk wires; and wherein there is no overall shielding metal foil or braiding around the bundle of the conductors.

8. The Long-Distance DC-DC Converter Circuitry system comprising:
a long cable comprising conductors
a wrapping and jacket surrounding the conductors forming a bulk wire;
a male or female connector on each end of the long cable;
a first and second device, wherein each device can connect to circuitry configured in the long cable; the circuitry further comprising:
a first DC-DC converter to convert an external power from the near end connector of the long cable connected to an external device into an Inner Power with a different voltage;
wherein the first DC-DC converter sends the Inner Power to the far end of the long cable via the conductors in the bulk wire;
a second DC-DC converter wherein the Inner Power received at the far end of the long cable is sent from the first DC-DC converter to convert to another voltage needed from a first or second device and that feeds to the other circuits in the far end of the long cable;
wherein the converted voltage is also fed to the second device connected to the far end of the cable;
the circuitry in the cable further comprising an “OR” circuit formed by a diode or other components that only allows the power with higher voltage to go through to the connected external first or second device between the converted power via the Inner Power conductor and the not converted power via the standard conductor of the bulk wires

9. The Long-Distance DC-DC Converter Circuitry in claim 8, further comprising Legacy Upgrading Circuitry, the Legacy Upgrading Circuitry further comprising:
an electronic switch component connecting in between the near end and far end of the standard power conductor,
a Control circuit that acts based on the voltage of the standard power conductor of the long cable's near end;
a Switch;
wherein the voltage of the standard power conductor's near end is in some ranges, the Control circuit will turn on the Switch and connect the near end and far end of the standard power conductors together as one wire;
while when the voltage of the standard power conductor's near end is in another range, the Control circuit will turn off the Switch and disconnect the near end and far end of the standard power conductors thus allow the near end and far end of these standard power conductors to have different voltages.

10. A PD Adapter accessory comprising:
a first and second connector body;
a short bulk wire comprising conductors comprising a first end and a second end wherein the first end is connected to the first connector body and the second end is connected to the second connector body;
a communications conductor disposed inside the short bulk wire a female connector disposed on the first or second connector body;
a male connector disposed on the first or second connector body;
a printed circuit board (PCB) configured inside the first end of the connector body further comprises a PD Controller micro controller IC, wherein the PD Controller communicates with a device connected to the female end of the PD Adapter and with a device connected to the male end of the PD Adapter separately with different parameters via the communication conductor;
optionally a DP Controller micro controller IC in between the input and output of this adapter to manage the number of USB-C signal lanes to be used for DP video; and
firmware embedded in or loadable into the PD Adapter wherein the firmware can be updated by user to expand the incompatibility fixes or adding features.

11. A long communication cable comprising:
a cable comprising conductors; wherein at least one of the conductors is an Inner Power (Vint) conductor;
at least two connectors for connecting to a display and a source device;
at least two active optical cable circuits;
a plurality of circuitry further comprising;
at least one Long-Distance DC-DC Converter Circuitry; and
optionally a Legacy Upgrading Circuitry
optionally a balanced long-distance driver and transmission circuitry.

12. The long communication cable of claim 11 wherein the Long-Distance DC-DC Converter Circuitry further comprises:
at least one of the DC-DC converters;
wherein the first DC-DC converter increases a voltage from a connected display to a set voltage; the second DC-DC converter decreases the voltage to a lower standard set voltage for use by a connected first active optical cable circuit; and the third DC-DC converter decreases the voltage for use by a second connected active optical cable circuit and a connected source device.

13. The long communication cable of claim 11, wherein the Vint conductor is configured to carry about 5 V to about 48 V.

14. The long communication cable of claim 11, wherein the balanced long-distance transmission circuitry further comprises balanced conductors (3 conductors: + and − and ground) chosen from the group consisting of a CC conductor, a Sbu1/2 conductor, and a D+/− conductor.

15. The long communication cable of claim 11, wherein the voltage converted is from about 5 V, about 9 V, about 15 V or about 20 V, to up to about 48 V.

16. A long communication cable of claim 11, further comprising some or all of the circuitries in the Dongles of claim 3 and/or PD Adapter of claim 10 incorporated into the long communication cable to achieve the features of the external Dongles and/or PD Adapter.
